(19) United States
(12) Patent Application Publication
(10) Pub. No.: US 2013/0069128 A1
(43) Pub. Date: Mar. 21, 2013

(54) SEMICONDUCTOR DEVICE AND MANUFACTURING METHOD OF THE SAME

(71) Applicant: Kimitoshi OKANO, Yokohama-shi (JP)

(72) Inventor: Kimitoshi OKANO, Yokohama-shi (JP)

(21) Appl. No.: 13/603,754

(22) Filed: Sep. 5, 2012

(30) Foreign Application Priority Data
Sep. 16, 2011 (JP) 2011-203001

(51) Int. Cl. H01L 29/78; H01L 21/336

(52) U.S. Cl. 257/288; 438/197; 257/E29.255; 257/E21.409

(57) ABSTRACT

According to the embodiments, a semiconductor device includes a first semiconductor layer which has a projection extending along a surface of the first semiconductor layer. A gate electrode is over a surface of the projection with an intervening gate insulator. A second semiconductor layer on a portion of the side surface of the projection other than a portion covered with the gate electrode has a trench. A source/drain area is formed in the second semiconductor layer. A silicide film is over a surface of the second semiconductor layer including a surface in the trench. A conductive plug contacts the silicide film.

### CROSS-REFERENCE TO RELATED APPLICATIONS

This application is based upon and claims the benefit of priority from Japanese Patent Application No. 2011-203001, filed Sep. 16, 2011, the entire contents of which are incorporated herein by reference.

### FIELD

Embodiments described herein relate generally to a semiconductor device and a manufacturing method of the same.

### BACKGROUND

A fin field-effect transistor (finFET) uses extending semiconductor (fin) as its channel. It has the structure where a gate electrode covers a fin channel with an intervening gate insulator on the surface of the fin. A reduced fin width than the gate length can increase dominance of the gate electrode over the channel potential, which can in turn inhibit the short channel effect without increasing an impurity concentration in the channel. For this reason, the finFET advantageously has a high carrier-mobility in the channel and low variation in the threshold voltage due to impurity fluctuations; however, an increased parasitic resistance resulting from the narrow fin degrades performance of the device.

### BRIEF DESCRIPTION OF THE DRAWINGS

FIG. 1 illustrates a sectional view of a state in a manufacturing process of a semiconductor device for reference.

FIG. 2 illustrates a state following FIG. 1.

FIG. 3 illustrates a state following FIG. 2.

FIGS. 4A, 4B, and 4C illustrate sectional views of a state in the manufacturing process of the semiconductor device according to a first embodiment.

FIG. 5 illustrates a plan view of a state in the manufacturing process of the semiconductor device according to the first embodiment.

FIG. 6 illustrates a sectional view of a state following FIG. 4A.

FIG. 7 illustrates a sectional view of a state following FIG. 6.

FIG. 8 illustrates a sectional view of a state following FIG. 7.

FIGS. 9A and 9B illustrate sectional views of a state following FIG. 8.

FIG. 10 illustrates a sectional view of a state following FIG. 9.

FIG. 11 illustrates a sectional view of a state following FIG. 10.

FIG. 12 illustrates a sectional view of a state following FIG. 11.

FIG. 13 illustrates a sectional view of a state following FIG. 12.

FIG. 14 illustrates a sectional view of a state following FIG. 13.

FIG. 15 illustrates a sectional view of a state following FIG. 14.

FIG. 16 illustrates a sectional view of a state following FIG. 15.

FIG. 17 illustrates a sectional view of a state in a manufacturing process of a semiconductor device according to a modified first embodiment.

FIG. 18 illustrates a sectional view of a state following FIG. 17.

FIG. 19 illustrates a sectional view of a state in a manufacturing process of a semiconductor device according to a second embodiment.

FIG. 20 illustrates a sectional view of a state following FIG. 19.

FIG. 21 illustrates a sectional view of a state following FIG. 20.

FIG. 22 illustrates a sectional view of a state following FIG. 21.

FIG. 23 illustrates a sectional view of a state following FIG. 22.

FIG. 24 illustrates a sectional view of a state following FIG. 23.

FIG. 25 illustrates a sectional view of a state in a manufacturing process of a semiconductor device according to a modified second embodiment.

FIG. 26 illustrates a sectional view of a state following FIG. 25.

### DETAILED DESCRIPTION

In general, according to one embodiment, a semiconductor device includes a first semiconductor layer which has a projection extending along a surface of the first semiconductor layer. A gate electrode is over a surface of the projection with an intervening gate insulator. A second semiconductor layer on a portion of the side surface of the projection other than a portion covered with the gate electrode has a trench. A source/drain area is formed in the second semiconductor layer. A silicide film is over a surface of the second semiconductor layer including a surface in the trench. A conductive plug contacts the silicide film.

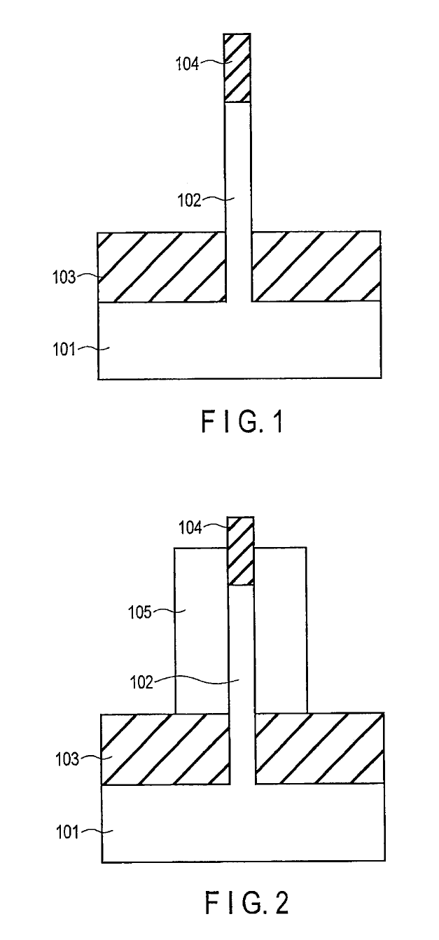

The inventor obtained the following knowledge in the course of developing the embodiments. In order to reduce a large parasitic resistance resulting from the above fine fin, it is widely executed to epitaxially grow a semiconductor layer for source and drain after formation of a gate sidewall, and then to form a silicide on its surface. Specifically, as shown in FIG. 1, a fin 102 is formed on a substrate 101 of, for example, silicon. 103 are shallow trench isolations (STIs), and 104 is a cap film of, for example, an insulator. The surface of the fin 102 has been already partly covered with a plate-shape gate electrode which perpendicularly intersects the fin at the step shown in FIG. 1. The gate electrode is provided in a sectional view different from that shown in FIG. 1, and therefore not shown in FIG. 1. An offset spacer film covering the fin 102 is then formed, source/drain extensions are formed by ion implantation through the offset spacer film. A sidewall spacer film is formed on the surface of the offset spacer film, and the offset spacer film and sidewall spacer film are processed simultaneously to form an offset spacer and a sidewall spacer. The offset spacer and sidewall spacer are formed on the side surfaces of the gate electrode to serve to electrically insulate the gate electrode from its surrounding conductor. Since they are processed not to remain on where source/drain areas will be formed, they do not appear in the sectional view of FIG. 1, which corresponds to the source/drain areas.

As shown in FIG. 2, a semiconductor layer 105, which will result in the source/drain areas, is epitaxially grown with the fin 102 used as the base. FIG. 2 illustrates a case where the side surfaces of the fin have (100) plane orientation. As shown in FIG. 2, the semiconductor layer 105 covers both side surfaces of the fin. Ions are then implanted into the semiconductor layer 105 to form the source/drain areas in the semiconductor layer 105.

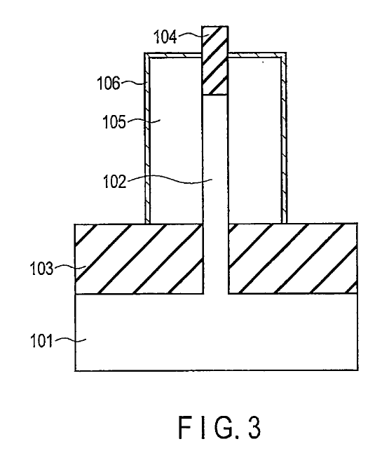

As shown in FIG. 3, a silicide film 106 is then formed on the surface of the semiconductor layer 105. An interlayer insulator and a contact plug (not shown) are then formed.

The dominant factor of the parasitic resistance of the source/drain areas 105 is the resistance at the interface between the silicon source/drain areas 105 and silicide film 106. Therefore, reducing the interface resistance is the key to improve the performance of the finFET. The following three approaches are effective for reducing the interface resistance. The first one is to reduce the Schottky barrier height formed in the interface. The Schottky barrier height depends on the material of silicide and its phase. The second one is to increase the concentration of impurities in the interface. The third one is to increase the area of the interface, i.e., the contacting area between the source/drain areas 105 and silicide film 106. At present, there are few proposals of effective techniques for increasing the contact areas.

Embodiments configured based on such findings will now be described with reference to figures. Components with substantially the same functions and configurations will be referred to with the same reference numbers and duplicate descriptions will be given only when required. Note that the figures are illustrative and the relationship between the thickness and the plane dimension of a film and the ratios of the thickness of one layer to another may differ from actual values. A specific thickness and dimension should be determined in accordance with the following description. Moreover, it is natural that different figures may contain a portion different in relationship and/or ratio of dimensions.

Moreover, each embodiment described in the following only illustrates a device and method which embody the technical idea of the embodiment, and the technical idea does not limit the material, form, structure or arrangement of components to the following. The technical idea of the embodiments can be variously modified within the scope of claims.

### First Embodiment

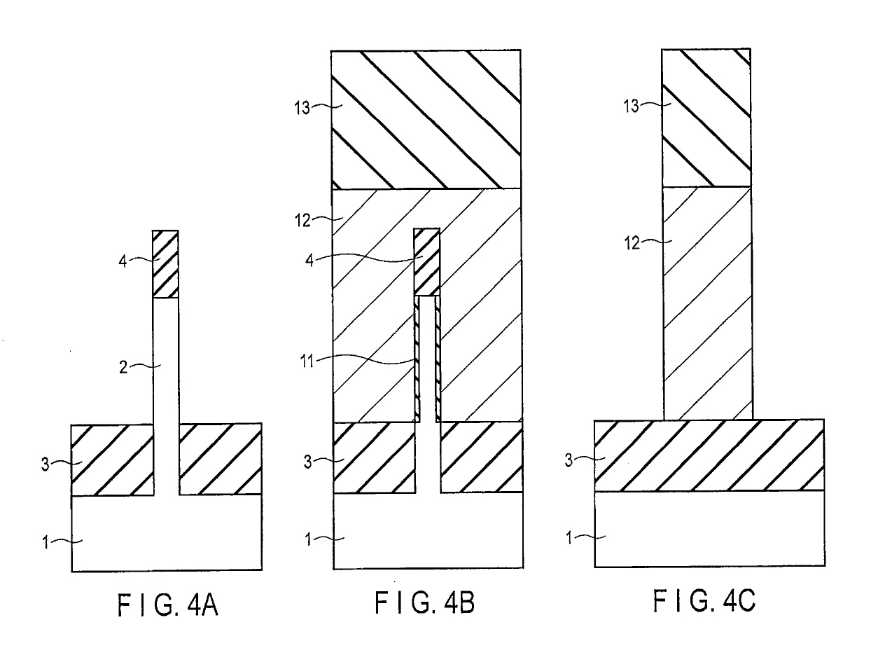

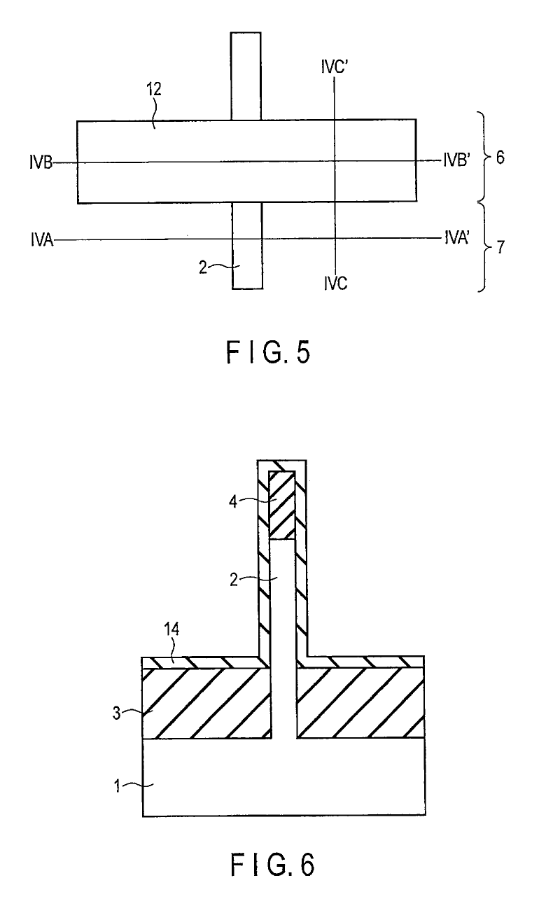

FIG. 4 illustrates a sectional view of a state in a manufacturing process of a semiconductor device according to the first embodiment. FIGS. 4A, 4B, and 4C illustrate sectional views along IVA-IVA′, IVB-IVB′, and IVC-IVC′ of FIG. 5, respectively. FIG. 5 illustrates a plan view of a state in the manufacturing process of the semiconductor device according to the first embodiment.

As shown in FIGS. 4A to 4C, a fin (projection) 2 is formed on a surface of a substrate 1 of, for example, silicon. The fin 2 has a plane extending along one direction (i.e., the direction extending between the top and the bottom of FIG. 5) and has a width of 10 to 30 nm, and its side surfaces have (100) plane orientation. In order to form the fin 2, a cap film 4 which covers where the fin 2 will be formed and has openings in remaining areas is formed. The cap film 4 may consist of Si₃N₄, for example. The substrate 1 is then patterned by anisotropic etching such as reactive ion etching (RIE) with the cap film 4 used as a mask to form the fin 2. The surface of the substrate 1 in the areas other than the fin 2 is formed with shallow trench isolations (STIs) 3 of an insulator. The STI 3 serves as an element isolation layer.

A part of the fin 2 in a direction along the fin-extending direction is covered with a gate electrode 12 with intervening gate insulators 11 formed on the side surfaces of the fin 2. FIG. 4B illustrates a sectional view of a channel region including the gate insulators 11 and gate electrode 12. The gate insulators 11 are formed on both side surfaces of the fin 2, and may include silicon oxide, for example. The gate insulators 11 and cap film 4 are covered with the gate electrode 12. An area of the fin 2 covered with the gate insulators 11 and gate electrode 12 is a part of the fin 2 along the direction in which the fin 2 extends as shown in FIG. 5. The area with the gate electrode 12 is referred to as a gate electrode section 6 hereinafter. In contrast, the area which does not include the gate electrode 12 is referred to as a source/drain section 7.

The gate electrode 12 extends along a direction which traverses, typically perpendicularly traverses the fin 2. In order to form the gate electrode 12, the fin 2 is first formed and the gate insulators 11 are formed on the fin side surfaces, and then a conductive film used as a material for the gate electrode 12 is formed above the whole surface of the substrate 1 and STIs 3, followed by formation of an insulator such as Si₃N₄ used as a material for the cap film 13 on the conductive film. The cap film 13 serves as a hard mask for processing the gate electrode, and is formed above where the gate electrode 12 will be formed. The conductive film is then patterned by anisotropic etching such as RIE with the cap film 13 used as a mask to form the gate electrode 12.

The subsequent FIGS. 6 to 8 only illustrate sectional views of the source/drain section 7, i.e., sectional views corresponding to FIG. 4A sequentially along with the manufacturing process. Following FIG. 4A, as shown in FIG. 6, the entire surface of the structure obtained by the process so far is covered with an offset spacer film 14 of, for example, Si₃N₄. Specifically, in the sectional view of FIG. 6, the offset spacer film 14 covers the STIs 3, fin 2, and cap film 4, whereas in the gate electrode section 6 (i.e., section IVB-IVB′ of FIG. 5), it covers the gate electrode 12 and cap film 13.

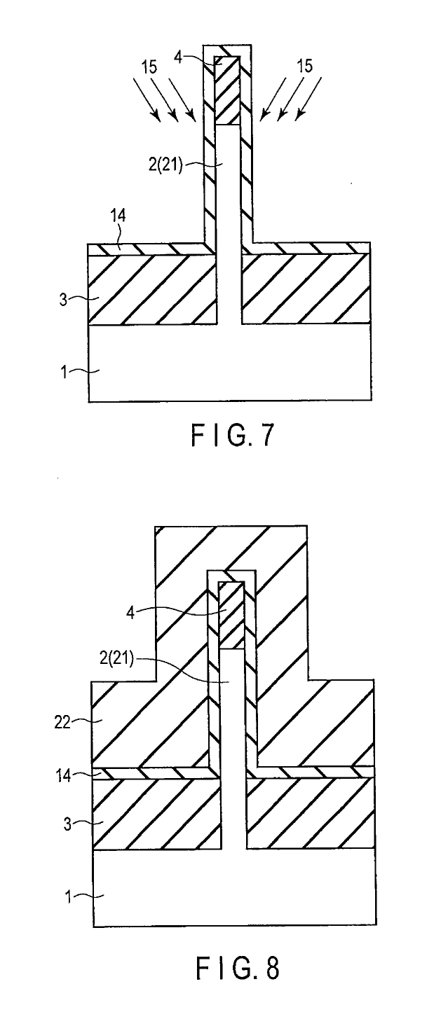

As shown in FIG. 7, in the source/drain section 7, impurities are introduced into the fin 2 through the offset spacer film 14. The impurity implantation is performed using tilted ion implantation 15 to the fin 2, for example. During this step, the impurities are introduced into an area of the fin 2 above the STI surface to form source/drain extension areas 21.

As shown in FIG. 8, Si₃N₄ is formed over the offset spacer film 14 as a material to form sidewall spacers 22.

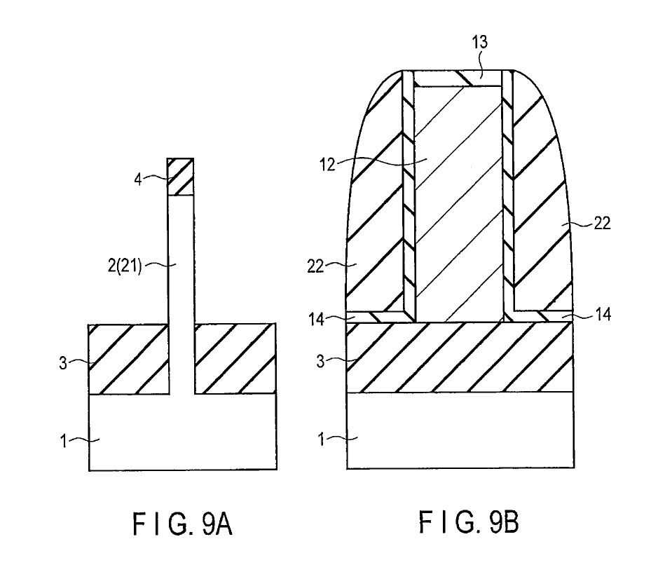

The subsequent FIG. 9A illustrates the source/drain section resulting from processing the sidewall spacers using RIE to the state of FIG. 8, and FIG. 9B illustrates the gate electrode section 6, i.e., the section along IVC-IVC′ of FIG. 5. As shown in FIG. 9A, in the source/drain section 7, the sidewall spacer 22 and offset spacer film 14 are completely removed, and a part of the fin 2 above the STI surfaces is exposed. In contrast, as shown in FIG. 9B, in the gate electrode section 6, the offset spacer film 14 and sidewall spacers 22 remain to completely cover the side surfaces of the gate electrode 12. Completely eliminating the sidewall spacer 22 and offset spacer film 14 in the source/drain section 7 while leaving them to completely cover the side surfaces of the gate electrode 12 in the gate electrode section 6 can be performed by over-etching the offset spacer film 14 and sidewall spacer 22 using the height difference between a part of the fin 2 above the STI surfaces and the gate electrode 12 although the cap films 13 and 4 must have respective thicknesses sufficient to leave the cap film 13.

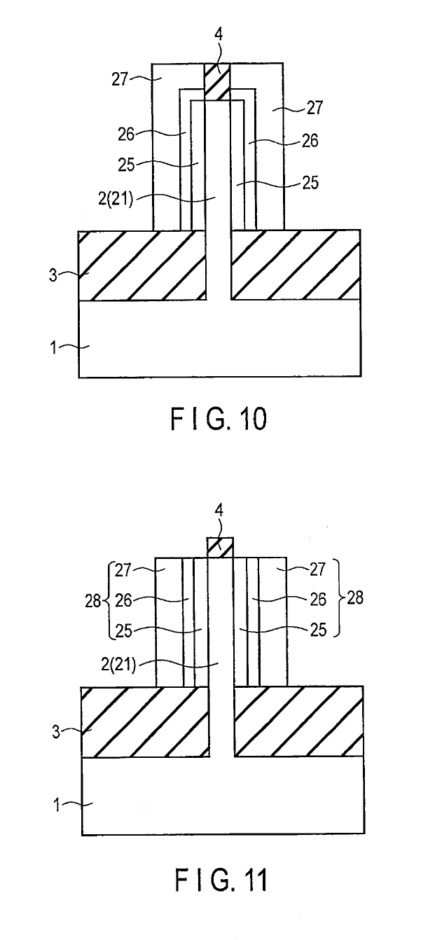

The subsequent FIGS. 10 to 16 only illustrate the source/drain section 7, i.e., the section corresponding to FIG. 4A sequentially along the manufacturing process. As shown in FIG. 10, a first film 25 of a first material, a second film 26 of a second material, and a third film 27 of the first material are formed in succession by epitaxial growth on both side surfaces of the fin 2 of the source/drain section 7. The first and second materials are selected so that they are etched at a different rate to a specific etching. In particular, the first and second materials are preferably selected to allow for a large etching selectivity between them. Specifically, one of the first and second materials may be silicon, and the other silicon germanium. Alternatively, the combination of the first and second materials may be silicon and silicon carbon, respectively. The first film 25 and the third film 27 may not be different materials. The material for the first film 25 and that for the third film 27 only need have the etching selectivity to the material for the second film 26.

The first film 25 is formed on the side surfaces of the fin 2. The second film 26 is then formed on the first film 25 on its exposed side surfaces and upper surface. The third film 27 is then formed on the second film 26 on its exposed side surfaces and upper surface.

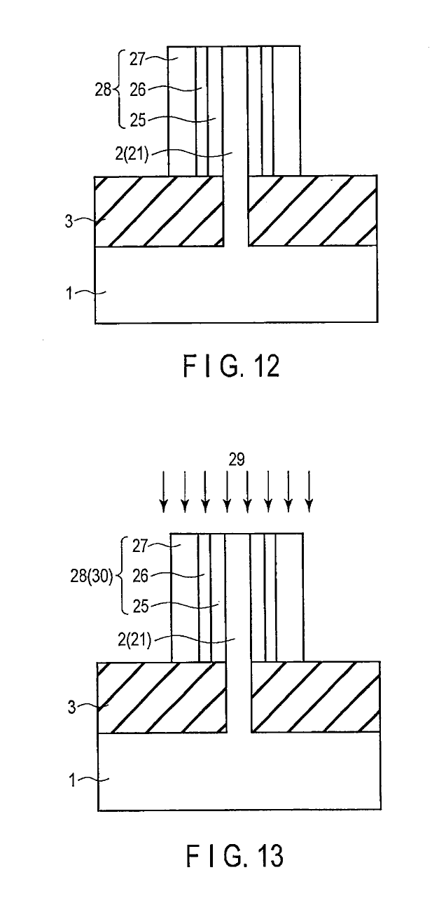

As shown in FIG. 11, the upper surfaces of the first, second, and third films 25, 26, and 27 are then caused to recede by anisotropic etching such as RIE. As a result, the upper surfaces of the first and second films 25 and 26 are exposed. The step of causing this recession also lowers the upper surface of the cap film 4. The structure including the first, second, and third films 25, 26, and 27 configure a semiconductor layer 28 for source/drain areas. As shown in FIG. 12, the cap film 4 is then removed by wet etching.

As shown in FIG. 13, impurities for forming source/drain areas are introduced into the semiconductor layer 28 and the already impurity-doped fin area 21 through the sidewall spacer 22 (not shown) to form source/drain areas 30, only one of which is illustrated in the figure.

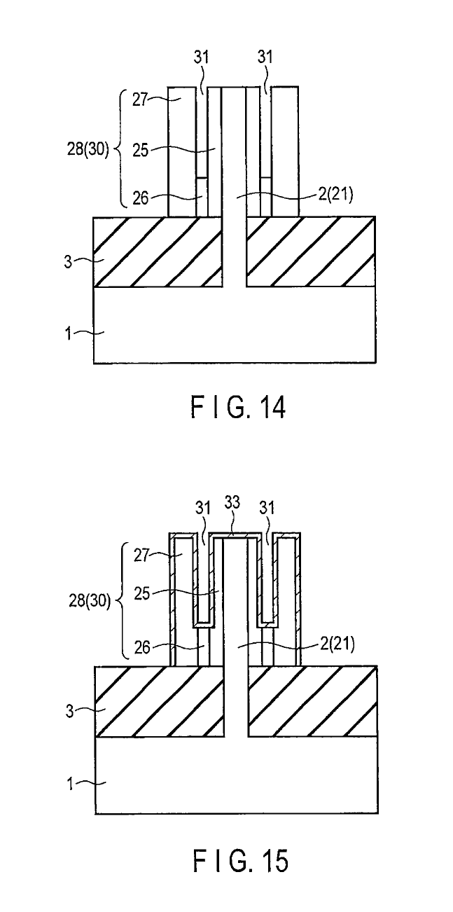

As shown in FIG. 14, a part of each second film 26 among the first, second, and third films 25, 26, and 27 is removed. This selective removal is executed by etching with a selectivity between the first material for the first and third films 25 and 27 and the second material for the second film 26. For example, when the first and third films 25 and 27 include silicon and the second film 26 include silicon germanium, the selective etching can be executed by wet etching with mixed solution of peracetic acid and hydrofluoric acid. The second film 26 is thus selectively etched to form trenches 31 between the first and third films 25 and 27. In the trenches 31, the side surfaces of the first and third films 25 and 27 are exposed. The trenches 31 may reach deeper than the half the thickness of the first and third films 25 and 27, and the second film 26 may remain at their bottoms, for example, in FIG. 14. Each of the second films 26 connects the first and third films 25 and 27. The deeper the trenches 31, the larger the surface area of the semiconductor 28. The degree of etching the second film 26 is controlled to prevent it from being completely removed.

The width of the trenches 31 can be varied by controlling the thickness of the second film 26. The depth of the trenches 31 can be varied by controlling the degree of recession of the upper surface of the second film 26. Thus, the dimensions of the trenches 31 can be controlled with the semiconductor layer 28 which includes materials different in etching rate. The figure illustrates a trench 31 present at each side of the fin 2; however there may be two trenches or more per one side. In order to form two trenches 31 on one side, additional films of the second and first materials must be formed on the outer surface of the third film 27.

As shown in FIG. 15, the silicide film 33 is then formed on the surface of the first, second, and third films 25, 26, and 27 (or, the semiconductor layer 28). In order to form the silicide film 33, a metal film to be the silicide film 33 is first formed on the surface of the first, second, and third films 25, 26, and 27. The metal may be Ni, Co, Ti, Pt, and Pd. Heat treatment is then performed to make the metal elements react with the silicon in the first, second, and third films 25, 26, and 27 to form the silicide film 33. The silicide film 33 covers the upper surface of the first film 25 and the inner side surface of the trenches 31 thereof, the upper surface of the second film 26, the upper and outer side surfaces of the third film 27 and the inner side surface of the trenches 31 thereof, and the upper surface of the fin 2. Since the first, second, and third films 25, 26, and 27 are formed by the epitaxial growth, they are single crystals. For this reason, the controllability of the thickness of the silicide film 33, and the resistance thereof excels in comparison with the case of a polycrystal. The semiconductor layer 28 consisting of the first, second, and third films 25, 26, and 27 has the trenches 31. For this reason, the semiconductor layer 28 has a surface area larger than it would have without a trench 31.

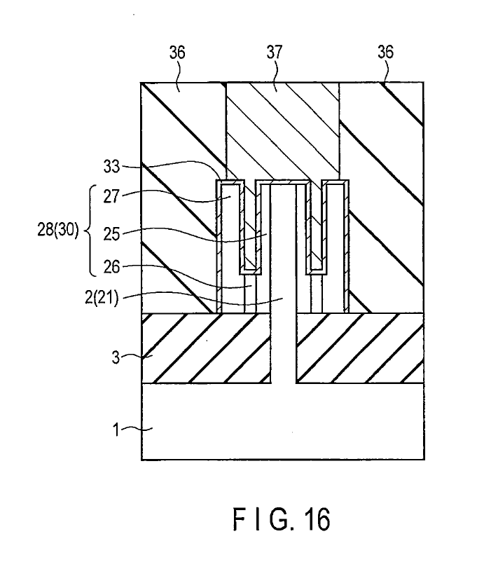

As shown in FIG. 16, an interlayer insulator 36 and a contact plug 37 are formed. Specifically, the interlayer insulator 36 may first be deposited by chemical vapor deposition (CVD) on the whole surface of the structure obtained so far. A mask with an opening where the contact plug 37 will be formed is then formed on the interlayer insulator 36, and a contact hole is formed in it by anisotropic etching such as RIE. During formation of the contact hole, the interlayer insulator 36 in the trenches 31 is also removed. The contact hole is then buried with conductive material for the contact plug 37. The contact plug 37 contacts the silicide film 33 on the upper surfaces of the first, second, and third films 25, 26, and 27, and the fin 2, and also buries the trench 31 to contact the silicide film 33 in the trench 31. The contact plug 37 preferably buries the trench 31 to connect the first film 25 and third film 27 in the trench 31; however, the contact plug 37 does not necessarily connect the first and third films 25 and 27 when the second film 26 remains. Thus, the finFET is completed.

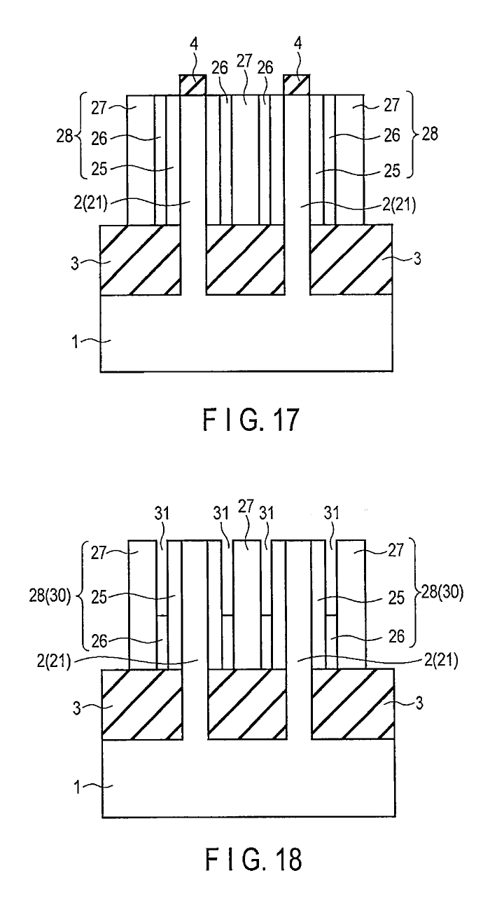

The finFET may include a type where a FET has two fins or more for its channel, which may be referred to as a multi-fin finFET. In the multi-fin finFET, a film epitaxially grown on the side surface of a fin for the source/drain areas may connect to another fin. The first embodiment is applicable to the multi-fin finFET. FIG. 17 illustrates a sectional view of a multi-fin finFET in one state in a manufacturing process of a semiconductor device according to a modified first embodiment. FIG. 17 illustrates a sectional view corresponding to the source/drain section 7, i.e., a sectional view corresponding to FIG. 4A. FIG. 18 illustrates a sectional view of a state following FIG. 17.

FIG. 17 corresponds to the state of FIG. 11. As shown in FIG. 17, the same processes described with reference to FIG. 1 are performed to form fins 2 (two fins illustrated) on the surface of the substrate 1. The fins have an interval which allows, when the third films 27 are formed later, the third films 27 for different fins 2 to connect to each other. The same processes as those described with reference to FIGS. 6 to FIGS. 9A and 9B, and FIG. 11 are performed to form the source/drain extensions 21, and the first, second, and third films 25, 26, and 27 on the both side surfaces of each fin 2. The third films 27 for the different fins 2 combine to bury the space between the fins 2 with the first, second, and third films 25, 26, and 27.

As shown in FIG. 18, the same processes as those described with reference to FIGS. 12 to 14 are then performed to form the source/drain areas 30 and to cause the upper surfaces of second films 26 to recede. As a result, the trenches 31 are formed in each space between the first and third films 25 and 27. The same process as that described with reference to FIG. 15 is then performed to form the silicide film 33. Similarly to FIG. 15, the silicide film 33 covers the upper surface of the first films 25 and the inner side surfaces of the trenches 31 thereof, the upper surfaces of the second films 26, the upper and outer side surfaces of the third films 27 and the inner side surfaces of the trenches 31 thereof, and the upper surfaces of the fins 2. The same process as that described with reference to FIG. 16 is then performed to form the interlayer insulator 36 and contact plug 37 which have the same structure as those in FIG. 16.

As described, according to the semiconductor device according to the first embodiment, the semiconductor layer 28, which consists of the first, second, and third films 25, 26 and 27 on the side surfaces of the fin 2, has the trenches 31. This allows the semiconductor layer 28 to have a larger surface area than it would without a trench 31 (as shown in FIG. 3, for example). Therefore, the silicide film 33 formed on such a semiconductor layer 28 including inside the trenches 31 has a surface area larger than it would without a trench 31. This can reduce the resistance at the interface between the semiconductor layer 28 and silicide film 33, which is the dominant factor of the parasitic resistance, to result in an improved performance of the finFET. This advantage is enhanced as the trenches 31 are deeper while leaving the second film 26. Moreover, the formation of the semiconductor layer 28 from materials with different etching rates to vary the contact area between the semiconductor layer 28 and silicide film 33 can control the property of the finFET.

### Second Embodiment

The first embodiment relates to the finFET whose fin side surfaces have (100) plane orientation, while the second embodiment relates to the finFET whose fin side surface have (110) plane orientation.

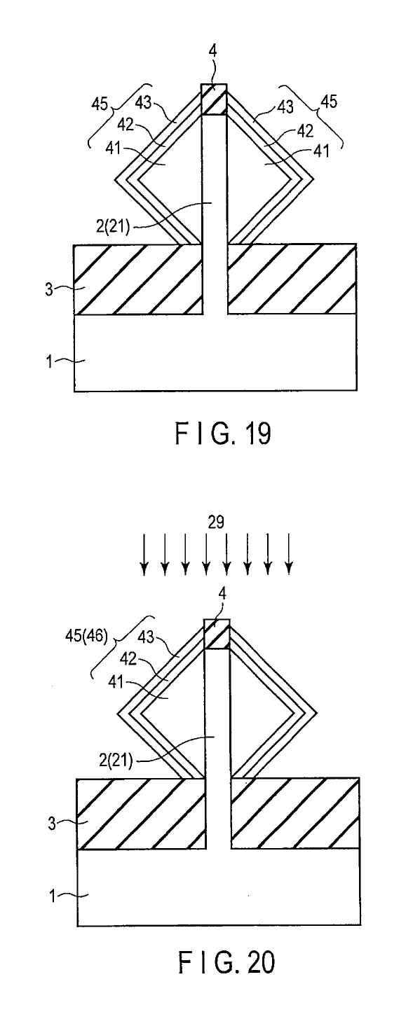

FIGS. 19 to 24 illustrate sectional views of states in a manufacturing process of a semiconductor device according to the second embodiment sequentially. FIGS. 19 to 24 illustrate the source/drain section 7, i.e., the sectional views corresponding to FIG. 4A of the first embodiment. The remaining structure of the section is the same as that of the first embodiment.

First, prior to the process of FIG. 19, the same processes as those described with reference to FIGS. 4A to 4C, FIGS. 6 to 9A and 9B are performed with the difference of the side surfaces of the fin 2 having (110) plane orientation as described above. As shown in FIG. 19, the same process as that described with reference to FIG. 10 is then performed to form first, second, and third films 41, 42, and 43. The first film 41 has a form different from that of the first film 25 of the first embodiment, and forms a rhombus defined by four (111) facet surfaces because the side surfaces of the fin 2 have (110) plane orientation. The second and third films 42 and 43 extend along the surface of the first film 41. The combination of the materials for the first, second, and third films 41, 42, and 43 has completely the same features as those for the first, second, and third films 25, 26, and 27 of the first embodiment. Specifically, the first and third films 41 and 43 typically consist of, or include, the first material, the second film 42 consists of, or include, the second material, and the first and second materials are etched at different rates to a specific etching. The specific examples are as described for the first embodiment. The structure which consists of the first, second, and third films 41, 42, and 43 configure a semiconductor layer 45 for source/drain areas.

As shown in FIG. 20, the same process as that described with reference to FIG. 13 is then performed to introduce impurities for the source/drain areas into the semiconductor layer 45 and the already impurity-doped fin area 21 through the sidewall spacer 22 (not shown) to form the source/drain areas 46.

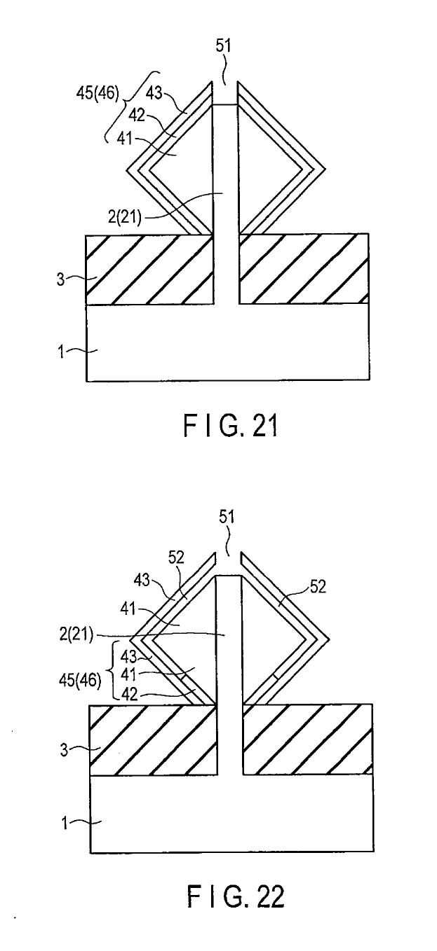

As shown in FIG. 21, the cap film 4 is removed by, for example, wet etching. As a result, a trench 51 is formed above the fin 2. The trench 51 is defined by the upper surface of the fin 2 as its bottom, and a stack of the second and third films 42 and 43 as its sidewalls. The second film 42 is exposed in the trench 51.

As shown in FIG. 22, the same process as that described with reference to FIG. 14 is performed to selectively remove a part of the second film 42. The first and third films 41 and 43 remain. This selective removal is performed with a solution which reached the surface of the second film 42 from the side surfaces of the trench 51, starts from these surfaces, and progress as the second film 42 is removed along the direction where the second film 42 extends. As a result, trenches 52 are formed between the first and third films 41 and 43. The trenches 52 extend along the surface of the first film 41. FIG. 22 illustrates that the trenches 52 reach the lower sides of the first film 41, where the second film 42 remains, for example. The second film 42 connects the first film 41 and third film 43 to each other. The deeper the trenches 52, the larger the surface area of the semiconductor layer 45. The degree of etching the second film 42 is controlled to prevent it from being removed completely.

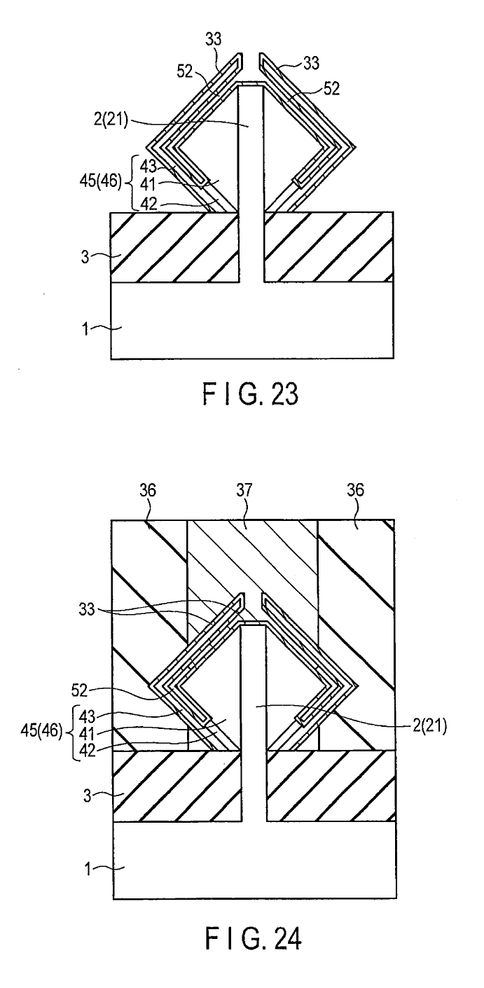

As shown in FIG. 23, the same process as that described with reference to FIG. 15 is then performed to form the silicide film 33 on the surface of the first, second, and third films 41, 42, and 43 (or, semiconductor layer 45). The silicide film 33 covers the surface of the first film 41 including inside the trenches 52, the upper surface of the second film 42, the surface of the third film 43 including inside the trenches 52, and the upper surface of the fin 2.

The semiconductor layer 45 consisting of the first, second, and third films 41, 42, and 43 has the trenches 52, and therefore, silicide film 33 and semiconductor layer 45 have a larger the surface area than it would without a trench 52. Therefore, the contact area between the silicide film 33 and the semiconductor layer of the films 41 to 43 is also larger than it would be without a trench 52.

As shown in FIG. 24, the same process as that described with reference to FIG. 16 is then performed to form the interlayer insulator 36 and contact plug 37. The contact plug 37 contacts the silicide film 33 on the upper surfaces of the first, second, and third films 41, 42, and 43, and buries the trenches 52 to contact the silicide film 33 in the trenches 52. The contact plug 37 preferably buries the trenches 52 to connect the first film 41 and third film 43 in the trenches 52. However, when the second film 42 remains, the contact plug 37 does not necessarily need to connect the first and third films 41 and 43. Thus, the finFET is completed.

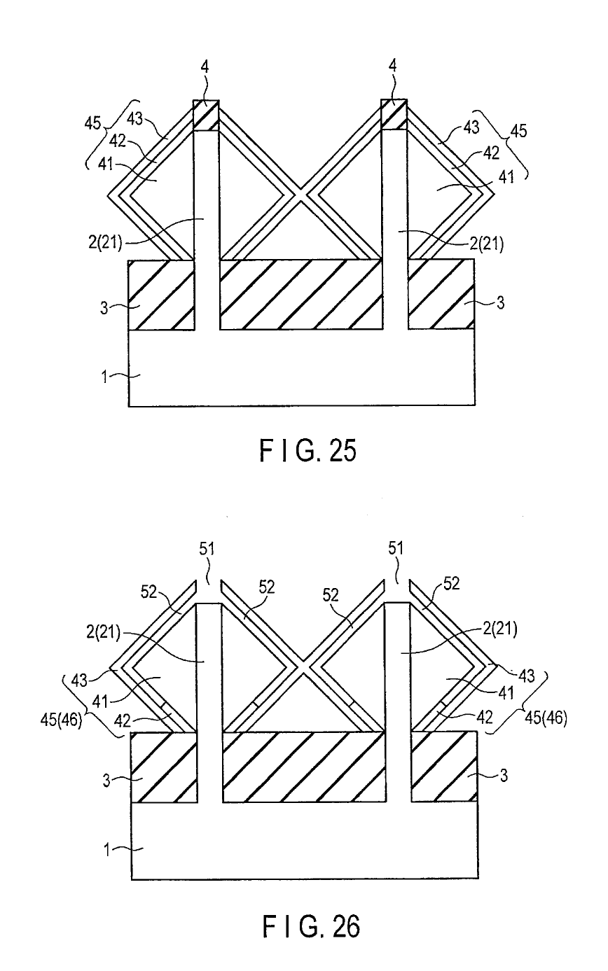

The second embodiment is also applicable to the multi-fin finFET as is the first embodiment. FIG. 25 illustrates a sectional view of one state in a manufacturing process of a semiconductor device according to a modified second embodiment. FIG. 26 illustrates a sectional view corresponding to the source/drain section 7 following FIG. 25.

FIG. 25 corresponds to the state of FIG. 19. As shown in FIG. 25, the same process as that described with reference to FIG. 1 is performed to form fins 2 (two fins illustrated) on the surface of the substrate 1. The fins have an interval which allows, when the third films 43 are formed later, the third films 43 for different fins 2 to connect to each other. The same processes as those described with reference to FIGS. 6 to FIGS. 9A and 9B are then performed to form the source/drain extensions 21. The same process as that described with reference to FIG. 19 is then performed to form the first, second, and third films 41, 42, and 43 on both side surfaces of each fin 2. The third films 43 for the different fins 2 combine.

As shown in FIG. 26, the same processes as those described with reference to FIGS. 20 to 22 are performed to remove a part of the second films 42 from their surfaces in the trenches 52 along the direction where the second films 42 extend. As a result, the trenches 52 are formed between the first and third films 41 and 43. The same process as that described with reference to FIG. 23 is then performed to form the silicide film 33. The silicide film 33 covers the surfaces of the first films 41 including inside the trenches 52, the upper surfaces of the second films 42, the surfaces of the third films 43 including inside the trenches 52, and the upper surfaces of the fins 2 as in FIG. 23. The same process as that described with reference to FIG. 24 is then performed to form the interlayer insulator 36 and contact plug 37 which have the same structure as those in FIG. 24.

As described, according to the semiconductor device of the second embodiment, the semiconductor layer 45, which consists of the first, second, and third films 41, 42 and 43 on the side surfaces of the fin 2, has the trenches 52 as in the first embodiment. This can reduce the resistance at the interface between the semiconductor layer 45 and silicide film 33 with the same mechanism as the first embodiment. This advantage is enhanced as the trenches 52 are deeper while leaving the second film 42 remains. Moreover, the formation of the semiconductor layer 45 from materials with different etching rates to vary the contact area between the semiconductor layer 45 and silicide film 33 can control the property of the finFET as in the first embodiment.

For the features not described in the second embodiment, the corresponding description in the first embodiment applies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer which has a projection extending along a surface of the first semiconductor layer;
a gate electrode over a surface of the projection with an intervening gate insulator;
a second semiconductor layer on a portion of the side surface of the projection other than a portion covered with the gate electrode, the second semiconductor layer having a trench;
a source/drain area formed in the second semiconductor layer;
a silicide film over a surface of the second semiconductor layer including a surface in the trench; and
a conductive plug which contacts the silicide film.

2. The device of claim 1, wherein
the second semiconductor layer comprises:
a first film on the side surface of the projection comprising a first semiconductor material;
a second film on a surface of the first film away from the first film, the second film comprising a second semiconductor material, having a different property from the first semiconductor material to an etching, and having an upper surface lower than the first film; and
a third film on a surface of the second film away from the first film, the third film comprising one of the first semiconductor material and a third semiconductor material and having an upper surface higher than the second film, the first and third films forming the trench above the second film.

3. The device of claim 1, wherein the plug contacts the silicide film in the trench.

4. The device of claim 3, wherein the plug buries the trench.

5. The device of claim 1, wherein the side surface of the projection has (100) plane orientation.

6. The device of claim 1, wherein the side surface of the projection has (110) plane orientation.

7. The device of claim 1, wherein the third film comprises the first semiconductor material.

8. The device of claim 7, wherein one of the first and second semiconductor materials comprises silicon, and the other comprises one of silicon germanium and silicon carbon.

9. The device of claim 1, wherein the first semiconductor layer has a second projection extending along the surface of the first semiconductor layer, and the second semiconductor layer contacts the side surface of the projection and a side surface of the second projection.

10. A method of manufacturing a semiconductor device comprising:
forming a first semiconductor layer which has a projection extending along a surface of the first semiconductor layer;
forming a gate electrode over a surface of the projection with an intervening gate insulator;
forming a second semiconductor layer on a portion of the side surface of the projection other than a portion covered with the gate electrode;
forming a source/drain area in the second semiconductor layer;
forming a trench in a surface of the second semiconductor layer;
forming a silicide film on the surface of the second semiconductor layer including an surface in the trench; and
forming a conductive plug which contacts the silicide film.

11. The method of claim 10, wherein the forming of the second semiconductor layer comprises:
forming a first film on the side surface of the projection, the first film comprising a first semiconductor material;
forming a second film on a surface of the first film away from the first film, the second film comprising a second semiconductor material, having a different property from the first semiconductor material to an etching;
forming a third film on a surface of the second film away from the first film, the third film comprising one of the first semiconductor material and a third semiconductor material, wherein
the forming of the trench comprises etching the second semiconductor material selectively to the first semiconductor material and the third semiconductor material to cause an upper surface of the second film to recede.

12. The method of claim 11, wherein the plug contacts the silicide film in the trench.

13. The method of claim 12, wherein the plug buries the trench.

14. The method of claim 10, wherein the side surface of the projection has (100) plane orientation.

15. The method of claim 10, wherein the side surface of the projection has (110) plane orientation.

16. The method of claim 10, wherein the third film comprises the first semiconductor material.

17. The method of claim 16, wherein one of the first and second semiconductor materials comprises silicon, and the other comprises one of silicon germanium and silicon carbon.

18. The method of claim 10, wherein the first semiconductor layer has a second projection extending along the surface of the first semiconductor layer, and the forming of the second semiconductor layer comprises forming the second semiconductor layer which contacts the side surface of the projection and a side surface of the second projection.
